(19) United States
(12) Patent Application Publication
(10) Pub. No.: US 2025/0363276 A1
(43) Pub. Date: Nov. 27, 2025

(54) AUTOMATIC TEST PATTERN GENERATION FOR ANALOG AND MIXED-SIGNAL CIRCUITS

(71) Applicant: Siemens Industry Software Inc., Plano, TX (US)

(72) Inventor: Stephen Kenneth Sunter, Nepean (CA)

(73) Assignee: Siemens Industry Software Inc., Plano, TX (US)

(21) Appl. No.: 18/869,627

(22) PCT Filed: Jun. 8, 2022
(86) PCT No.: PCT/US2022/072816

§ 371 Date: Nov. 26, 2024

(51) Int. Cl. G06F 30/333

(52) U.S. Cl. CPC G06F 30/333

(57) ABSTRACT

A method comprising: applying pre-determined DC voltage values to analog inputs of an analog or mixed signal circuit design (710); applying a plurality of sets of bit values generated for scan-based structural testing of circuits manufactured based on the circuit design, one set during each of a plurality of consecutive time intervals, to inputs of one or more node-connecting devices coupled to or to be coupled to one or more selected internal nodes of the circuit design, to one or more selected digital inputs of the circuit design, or both (720); and performing a simulation of the circuit design to determine, for each set of bit values, expected test response bit values at outputs of one or more threshold-comparing convertors and at selected digital signal nodes if the circuit design has the selected digital signal nodes (730). These operations may be repeated on the circuit design with defects being injected.

### FIELD OF THE DISCLOSED TECHNIQUES

The presently disclosed techniques relate to the field of testing analog and mixed-signal circuits. Various implementations of the disclosed techniques may be particularly useful for test pattern generation.

### BACKGROUND OF THE DISCLOSED TECHNIQUES

Integrated circuits are used in a wide range of applications such as consumer electronics, automotive, telecom, cloud computing, and artificial intelligence. While digital circuitry forms the core of most electronic systems today, these electronic systems are increasingly mixed-signal designs, embedding on a single die analog or mixed-signal blocks together with digital circuitry such as processors, logic blocks and memory blocks. Here, a mixed-signal block is a circuit block comprising both analog and digital circuitry.

The fabrication of integrated circuits comprises a series of photolithographic, printing, etching, implanting, and chemical vapor deposition steps. This process is subject to imperfections and can cause manufacture defects. The ever-continuing reduction in feature size further increases the probability of defective circuits. A very small defect may result in a faulty transistor or interconnecting wire. Even a single faulty transistor or wire can cause the entire chip to function improperly. It is thus necessary to test chips during the manufacturing process. Diagnosing faulty chips is also needed to ramp up and to maintain the manufacturing yield.

Testing typically includes applying a set of test stimuli (test patterns) to the circuit-under-test and then analyzing responses generated by the circuit-under-test. Functional testing attempts to validate that the circuit-under-test operates according to its functional specification. By contrast, structural testing tries to ascertain that the circuit-under-test has been assembled correctly from some low-level building blocks as specified in a structural netlist and these low-level building blocks and their wiring connections have been manufactured without defects. For structural testing, it is assumed that if functional verification performed during the design phase has shown the correctness of the netlist and structural testing during the manufacture phase has confirmed the correct assembly of the structural circuit elements, then the circuit should function correctly.

Structural testing has been widely adopted for testing digital circuits for the past several decades. One major advantage of structural testing is that it enables the test generation (test pattern generation) to focus on testing a limited number of relatively simple circuit elements rather than having to deal with an exponentially exploding multiplicity of functional states and state transitions. The current practice for testing analog and mixed-signal circuits, however, is still functional testing, also referred to as specification-based testing. Due to the nature of analog signals that are continuously changeable and various kinds of circuits for processing them, it is much more challenging to find a simple and universal mechanism to activate analog faults or defects and to capture test responses that require no complex analysis.

Despite the ease of interpreting the test result, specification-based testing relies on specialized automatic test equipment (ATE) with advanced capabilities and running the tests can take a long time. Moreover, specification-based testing can be very time-consuming to simulate because the complete end-to-end function is tested. Test generation automation has been developed only for very common and generic functions, like those of analog-to-digital converters (ADCs), digital-to-analog converters (DACs), phase-locked loops (PLLs), serializer/deserializer (SerDes), and voltage regulators. This relies on using stimuli and transfer function analysis that are specific to the generic function. No general method has been developed to generate tests for every type of circuit, especially for random analog circuitry.

Analog defect simulation, typically used to determine defect coverage of a test set, is also time-consuming. Unlike the often-used digital circuit fault model defined as a circuit node stuck at logic 0 or 1, modeling a short defect in an analog circuit typically comprises adding a 1-to-100 ohm resistor between two circuit nodes and modeling an open defect in an analog circuit typically comprises inserting a 0.1-to-10 Gohm resistor in a connection between two transistors. Each potential defect is simulated one at a time, and each such analog simulation can take minutes to days. With conventional technologies, the test equipment cost, test generation time, and test execution time have been and will continue to be impacted.

### BRIEF SUMMARY OF THE DISCLOSED TECHNIQUES

Various aspects of the disclosed technology relate to automatically generating test patterns for structural testing of analog and mixed-signal circuits. In one aspect, there is a method, comprising: applying pre-determined DC voltage values to analog inputs of a circuit design if the circuit design has the analog inputs, the circuit design being at least partially analog; applying a plurality of sets of bit values generated for scan-based structural testing of circuits manufactured based on the circuit design, one set of the plurality of sets of bit values during each of a plurality of consecutive time intervals, to inputs of one or more node-connecting devices coupled to or to be coupled to one or more selected internal nodes of the circuit design, to one or more selected digital inputs of the circuit design, or both, each of the one or more node-connecting devices configured to at least cause one of the one or more selected internal nodes to be either coupled to or decoupled from another node of the circuit based on bit values at inputs of the each of the one or more input node-connecting devices, each of the plurality of consecutive time intervals being equal to one or more clock cycles of a scan clock signal for the scan-based structural testing of circuits; and performing a simulation of the circuit design to determine, for each set of the plurality of sets of bit values, expected test response bit values at outputs of one or more threshold-comparing convertors and at selected digital signal nodes if the circuit design has the selected digital signal nodes, each of the one or more threshold-comparing convertors being coupled to or to be coupled to one of one or more selected nodes of the circuit design and comprising one or more threshold-comparing sub-convertors, each of the one or more threshold-comparing sub-convertors configured to output a bit value at one of outputs of the each of the one or more threshold-comparing convertors based on comparing a voltage value at the one of one or more selected nodes with one of one or more preset thresholds, wherein in the scan-based structural testing of circuits, at least some bits of the plurality of sets of bit values are applied to each of the circuits using one or more scan chains in the each of the circuits and test response bit values at at least some of the outputs of the one or more threshold-comparing convertors are captured by the one or more scan chains.

The bit value outputted by the each of the one or more threshold-comparing sub-convertors may be treated as being indeterminate if the voltage value at the one of one or more selected nodes is within a preset range centered at the one of the one or more preset thresholds. Alternatively or additionally, the bit value outputted by the each of the one or more threshold-comparing sub-convertors may be treated as being indeterminate if the performing a simulation is repeated for different combinations of process parameter values and the bit value is not the same for all of the different combinations of process parameter values.

The plurality of sets of bit values may be generated based on random combinations of bit values or all combinations of bit values. The one or more selected internal nodes and the one or more selected nodes may be selected based on user specification, circuit topology, or both.

The number of bit values at inputs of the each of the one or more input node-connecting devices may be either 1 or 2 and each of at least some of the one or more node-connecting devices may be configured to cause, based on a 2-bit value, a selected internal node to be coupled to either or neither of two other nodes of the circuit. Each of the one or more threshold-comparing sub-convertors may be implemented by an inverter and each of the one or more threshold-comparing convertors may comprise at most two threshold-comparing sub-convertors.

The method may further comprise: injecting defects into the circuit design; and performing the operations on the defected injected circuit design to determine a set of test patterns that can detect at least some of the defects. The defects may be injected into the circuit design one at a time for simulation. The method may still further comprise: determining a reduced set of test patterns that can detect the at least some of the defects based on the set of test patterns. The reduced set of test patterns may keep some consecutive test patterns in the set of test patterns. The determining a reduced set of test patterns may employ a greedy algorithm. The method may still further comprise: removing switching devices in the one or more node-connecting devices not uniquely contributing to detecting the defects, threshold-comparing sub-convertors in the one or more threshold-comparing convertors not uniquely contributing to detecting the defects, or both.

In another aspect, there are one or more non-transitory computer-readable media storing computer-executable instructions for causing one or more processors to perform the above method.

In still another aspect, there is a system, comprising: one or more processors, the one or more processors programmed to perform the above method.

Certain inventive aspects are set out in the accompanying independent and dependent claims. Features from the dependent claims may be combined with features of the independent claims and with features of other dependent claims as appropriate and not merely as explicitly set out in the claims.

Certain objects and advantages of various inventive aspects have been described herein above. Of course, it is to be understood that not necessarily all such objects or advantages may be achieved in accordance with any particular embodiment of the disclosed techniques. Thus, for example, those skilled in the art will recognize that the disclosed techniques may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1A illustrates an example scan chain.

FIG. 1B illustrates an example scan chain along with update storage elements.

FIG. 2 illustrates an example of scan-based test circuitry for testing an analog/mixed-signal circuit according to various embodiments of the disclosed technology.

FIG. 3A illustrates an example CMOS inverter serving as a threshold-comparing sub-convertor with a high threshold and its transfer function curve.

FIG. 3B illustrates an example CMOS inverter serving as a threshold-comparing sub-convertor with a low threshold and its transfer function curve.

FIG. 3C illustrates an example bias voltage generator.

FIG. 3D illustrates an example threshold-comparing convertor comprising two threshold-comparing sub-convertors that have two different thresholds and its transfer function curve.

FIG. 4A illustrates an example node-connecting device comprising a switching device implemented using a PMOS transistor.

FIG. 4B illustrates an example node-connecting device comprising a switching device implemented using an NMOS transistor.

FIG. 4C illustrates an example node-connecting device comprising two switching devices implemented using two transistors, respectively.

FIG. 5A illustrates an example circuit schematic diagram for an analog circuit.

FIG. 5B illustrates an example netlist for the analog circuit in FIG. 5A.

FIG. 5C illustrates example netlists for three node-connecting devices coupled to the three selected internal nodes for injecting test stimuli and an example netlist for a threshold-comparing convertor coupled to one of the three selected nodes for observing test responses.

FIG. 6 illustrates an example circuit schematic diagram for a circuit comprising both analog and digital circuitry.

FIG. 7 illustrates a flowchart showing a process of determining expected test responses for test patterns based on simulating a defect-free analog/mixed-signal circuit design that may be implemented according to various examples of the disclosed technology.

FIG. 8 illustrates an example of voltages applied to the analog inputs of the circuit in FIG. 5A, an example of nine sets of bit values applied as test stimuli to the circuit in FIG. 5A at nine consecutive time intervals, and an example of expected test response bit values captured during the nine consecutive time intervals.

FIG. 9 illustrates an example for determining indeterminate bits in the expected test response bit values for the circuit in FIG. 5A.

FIG. 10 illustrates a flowchart showing a process of simulating a plurality of defect-injected analog/mixed-signal circuit designs according to various embodiments of the disclosed technology.

FIG. 11 illustrates a flowchart showing a process of using a greedy algorithm to derive a reduced set of test patterns according to various embodiments of the disclosed technology.

FIG. 12A illustrates an example of forming a reduced set of test patterns based on a defect detection matrix for nine defects of the circuit in FIG. 5A.

FIG. 12B illustrates an example of forming a reduced set of short sequences of test patterns for testing the circuit in FIG. 5A.

FIG. 13A illustrates a set of test patterns applied to the circuit in FIG. 5A during nine consecutive time intervals.

FIG. 13B illustrates a reduced set of test patterns for three time intervals and without rows for the NMOS transistor (dftn0) and the PMOS transistor (dftp5).

FIG. 13C illustrates how the reduced set of three test patterns might be shifted in a serial bit stream applied to a scan chain.

FIG. 14A illustrates an example defect detection matrix for the circuit in FIG. 5A in terms of both the reduced set of test pattern bit locations and test response bit locations.

FIG. 14B illustrates an example of expected test response bit values for each of the threshold-comparing sub-convertors for nine consecutive time intervals with the reduced set of test patterns outlined.

FIG. 14C illustrates expected test response bit values only for three time intervals associated with the reduced set of test patterns.

FIG. 14D illustrates a minimized set of expected test response bit values only for the threshold-comparing sub-convertors retained.

FIG. 14E illustrates how the minimized set of expected test response bit values might be shifted out along a scan chain.

FIG. 15 illustrates an example of test circuitry for the circuit in FIG. 5A.

FIG. 16 illustrates an example of a programmable computer system with which various embodiments of the disclosed technology may be employed.

### DETAILED DESCRIPTION OF THE DISCLOSED TECHNIQUES

Various aspects of the disclosed technology relate to automatically generating test patterns for structural testing of analog and mixed-signal circuits. In the following description, numerous details are set forth for the purpose of explanation. However, one of ordinary skill in the art will realize that the disclosed technology may be practiced without the use of these specific details. In other instances, well-known features have not been described in details to avoid obscuring the disclosed technology.

Some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or on networked computers.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently. Moreover, for the sake of simplicity, the disclosed flow charts and block diagrams typically do not show the various ways in which particular methods can be used in conjunction with other methods.

The detailed description of a method or a device sometimes uses terms like “perform” and “apply” to describe the disclosed method or the device function/structure. Such terms are high-level descriptions. The actual operations or functions/structures that correspond to these terms will vary depending on the particular implementation and are readily discernible by one of ordinary skill in the art.

As used in this disclosure, the singular forms “a,” “an,” and “the” include the plural forms unless the context clearly dictates otherwise. Additionally, the term “includes” means “comprises.” Moreover, unless the context dictates otherwise, the term “coupled” means electrically or electromagnetically connected or linked and includes both direct connections or direct links and indirect connections or indirect links through one or more intermediate elements not affecting the intended operation of the circuit.

Additionally, as used herein, the term “design” is intended to encompass data describing an entire integrated circuit device. This term also is intended to encompass a smaller group of data describing one or more components of an entire device such as a portion of an integrated circuit device nevertheless.

As noted previously, testing typically includes applying test patterns to a circuit-under-test and then capturing and analyzing responses generated by the circuit-under-test. To make it easier to develop and apply test patterns, certain testability features are added to circuit designs, which is referred to as design for test or design for testability (DFT). Scan testing is the most common DFT method. In a basic scan testing scheme, all or most of internal sequential state elements (latches, flip-flops, et al.) in a circuit design are made controllable and observable via a serial interface. These functional state elements are usually replaced with dual-purpose state elements called scan cells. Scan cells are connected together to form scan chains-serial shift registers for shifting in test patterns and for capturing and shifting out test responses. Being dual-purpose, a scan cell can operate as a state element originally intended for functional purposes in functional/mission mode and as a unit in a scan chain for scan testing in test mode.

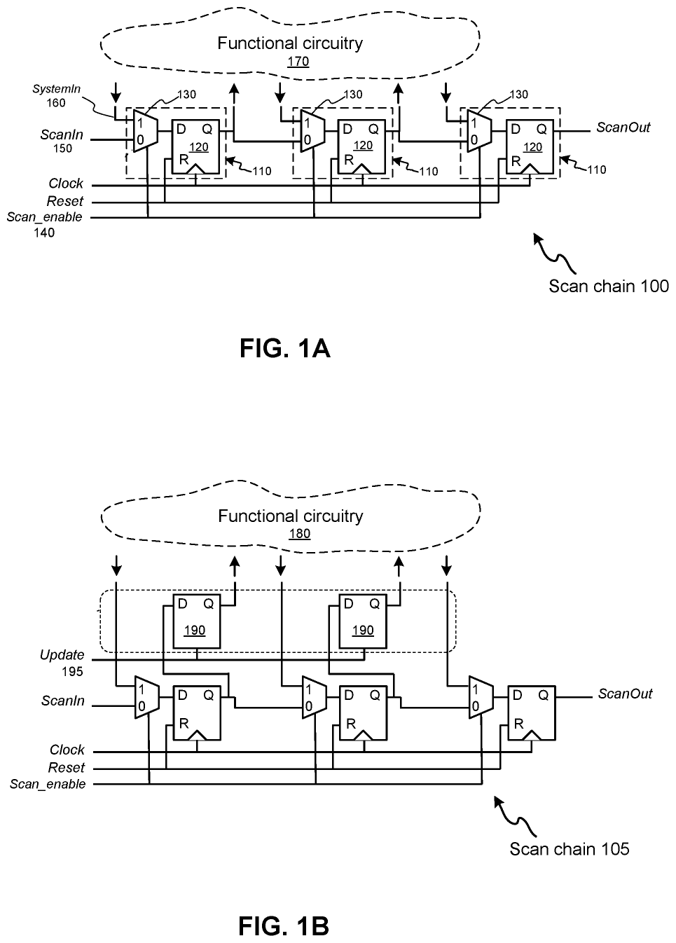

FIG. 1A illustrates an example of a scan chain 100. The scan chain 100 comprises a plurality of scan cells 110. Each of the scan cells 110 comprises an edge-trigged flip-flop 120 with a two-way multiplexer 130 for the data input. The two-way multiplexer 130 is typically controlled by a control signal 140 called scan_enable, which selects the input signal for the scan cell 110 from either a scan signal input port 150 or a system signal input port 160 (sometimes referred to as parallel input). The scan signal input port 150 is typically connected to an output of another scan cell in the scan chain 100 while the system signal input port 160 is connected to functional circuitry 170. Each of the scan cells 110 fans out into two outputs: a serial output coupled to the scan cell in the scan chain 100 and a parallel output coupled to functional circuitry 170.

In test mode, a scan cell like the scan cell 110 can serve as a control point that applies a test stimulus bit to the circuit-under-test, an observation point that captures a test response bit generated by the circuit-under-test, or both. Test mode typically includes two types of operations: shift operation (shift mode) and capture operation (capture mode). In the shift operation, a series of clock pulses, called “shift pulses” or “shift clock pulses,” are applied to the scan cells. Each shift clock pulse pushes a bit of a test pattern into a scan cell in each of the scan chains. This continues until all scan cells in the scan chains are filled with test pattern bits. In the capture operation, one or more clock pulses, called “capture pulses” or “capture clock pulses,” are applied to both the scan cells and the circuit-under-test as they would be in normal operation. After the test pattern bits stored in the scan cells are injected into the circuit-under-test, the results of the test (test responses) are “captured” and stored in the scan cells. The scan cells then return to the shift operation, and with each additional clock pulse, a bit of the test responses is pushed or shifted out along the scan chains as each bit of a new test pattern is pushed or shifted in. The shifted-out test responses are then compared with expected results to determine and locate any errors.

FIG. 1B illustrates another example of a scan chain 105. Unlike the scan chain 100 in FIG. 1A, parallel outputs of the scan chain 105 are coupled to functional circuitry 180 indirectly via update storage elements 190. The signals applied to the functional circuitry 180 can only change when an update clock signal 195 is toggled instead of whenever shifting occurs in the scan chain 105. This can prevent shifting from changing the state of the functional circuitry 180. Another benefit is the reduction of toggling activities in the shift operation which can significantly lower power consumptions and prevent the circuit from overheating. The update storage elements 190 can be implemented using latches or flip-flops.

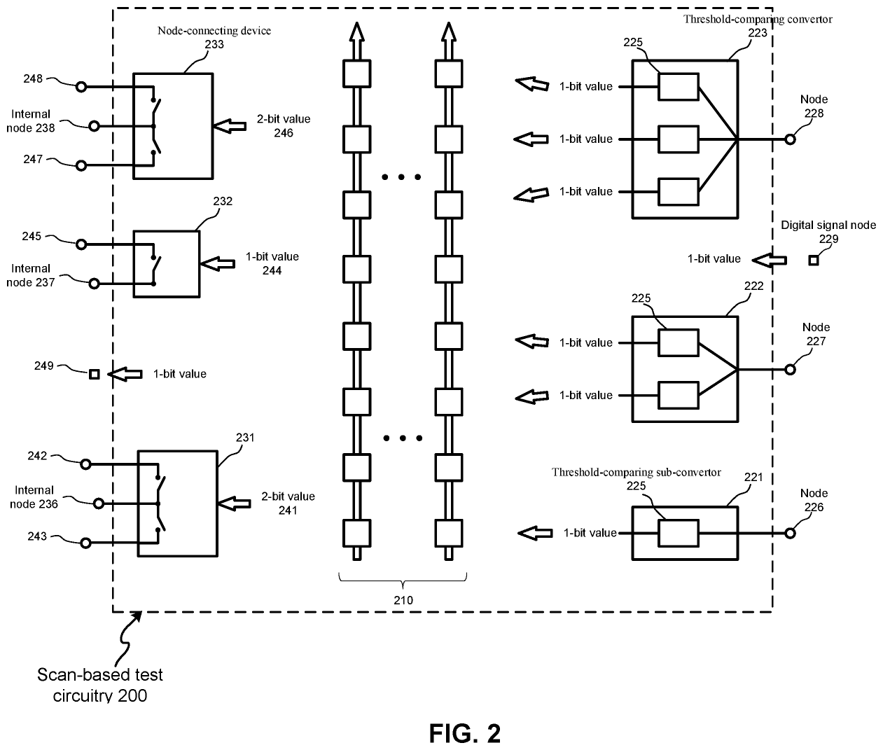

FIG. 2 illustrates an example of scan-based test circuitry 200 for testing an analog/mixed-signal circuit according to various embodiments of the disclosed technology. The scan-based test circuitry 200 comprises one or more scan chains 210, threshold-comparing convertors 221, 222 and 223, and node-connecting devices 231, 232 and 233. The one or more scan chains 210 are configured to shift in and apply test patterns, and to capture and shift out test responses during a test. The threshold-comparing convertors 221, 222 and 223 have inputs coupled to selected nodes 226, 227 and 228 of the analog/mixed-signal circuit, respectively and outputs coupled to parallel inputs of the one or more scan chains 210. The threshold-comparing convertors 221, 222 and 223 can be configured to convert voltages at the selected nodes 226, 227 and 228 into test response bit values which can then be captured by the one or more scan chains 210 during a test. The node-connecting devices 231, 232 and 233 have inputs coupled to parallel outputs of the one or more scan chains 210 and outputs coupled to selected internal nodes 236, 237 and 238 and their associated nodes of the analog/mixed-signal circuit, respectively. The node-connecting devices 231, 232 and 233 can be configured to apply test stimuli to the analog/mixed-signal circuit via the selected internal nodes 236, 237 and 238 and their associated nodes during a test based on test pattern bit values loaded in the one or more scan chains 210.

As shown in FIG. 2, the threshold-comparing convertors 221, 222 and 223 comprise one, two and three threshold-comparing sub-convertors 225, respectively. Each threshold-comparing sub-convertor 225 is configured to output a bit value based on comparing a voltage value at the associated selected node with a preset threshold. Specifically, the threshold-comparing convertor 221 can use one threshold-comparing sub-convertor 225 to convert the voltage at the selected node 226 into a one-bit test response value; the threshold-comparing convertor 222 can use two threshold-comparing sub-convertors 225 to convert the voltage at the selected node 227 into two one-bit test response values; and the threshold-comparing convertor 223 can use three threshold-comparing sub-convertors 225 to convert the voltage at the selected node 228 into three one-bit test response values. These digitized test response values can then be captured by the one or more scan chains 210. Typically, thresholds used by threshold-comparing sub-convertors in the same threshold-comparing convertor are set to be different from each other while thresholds used by threshold-comparing sub-convertors in different threshold-comparing convertors can be set to be the same or different.

Some circuits may have one or more digital signal nodes selected for observing test responses like a node 229. The test response bits at these selected digital signal nodes can be captured by the one or more scan chains 210 directly without using threshold-comparing convertors.

It should be noted that while the threshold-comparing convertors 221, 222 and 223 are shown to have at most three threshold-comparing sub-convertors, threshold-comparing convertors may comprise more than three threshold-comparing sub-convertors in some embodiments of the disclosed technology. In some other embodiments of the disclosed technology, each threshold-comparing convertor may comprise just one threshold-comparing sub-convertor. In still some other embodiments of the disclosed technology, each threshold-comparing convertor may comprise two threshold-comparing sub-convertors. It should also be noted that a scan chain can be coupled to outputs of a threshold-comparing convertor directly or indirectly. For example, a threshold-comparing convertor having four threshold-comparing sub-convertors can have outputs connected to an encoding device which is configured to convert a five possible output combination into a three-bit value. The outputs of the encoding device are connected to three scan cells of the scan chain.

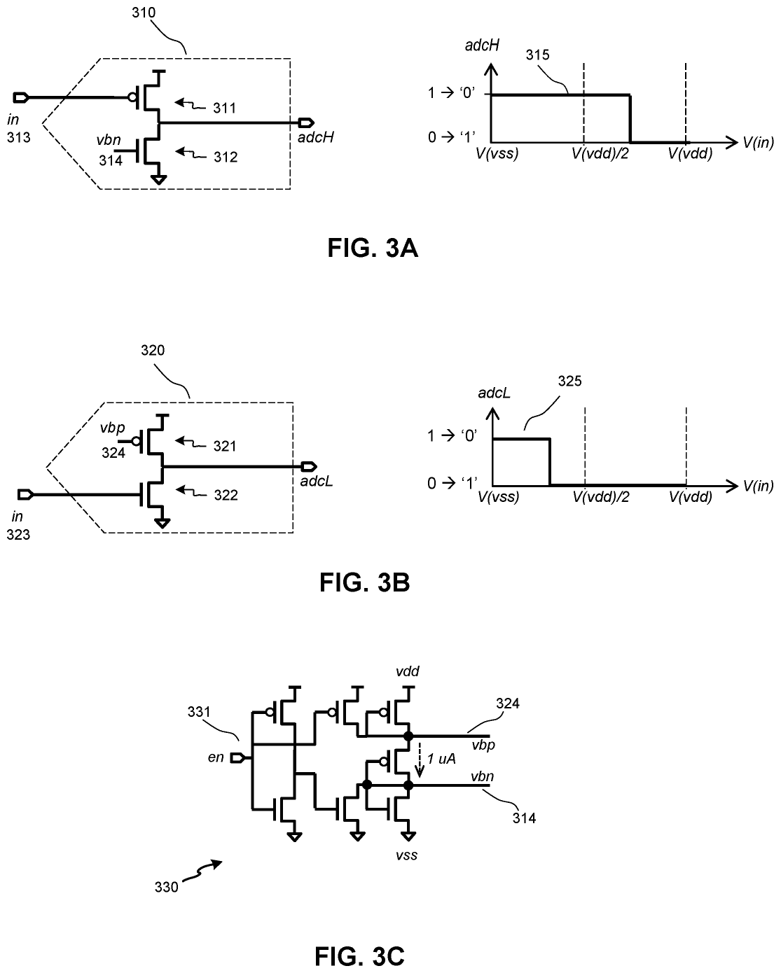

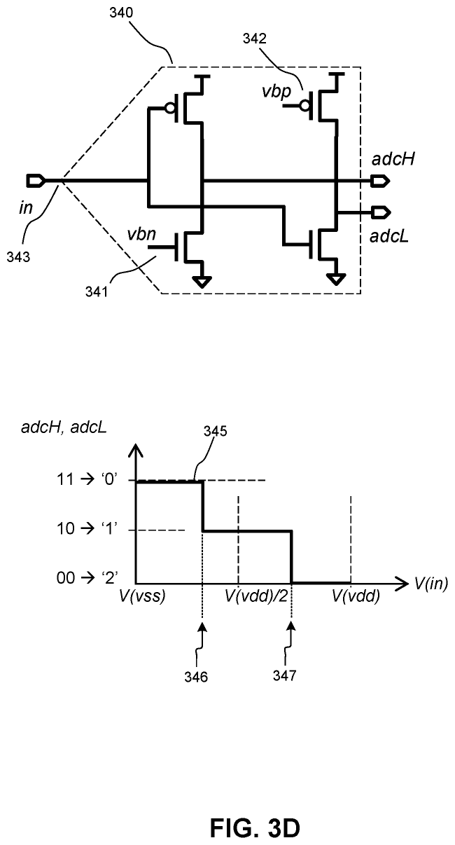

Threshold-comparing sub-convertors can be implemented using complementary metal-oxide semiconductor (CMOS) inverters. Each CMOS inverter can be constructed using a pair of p-type and n-type transistors. FIGS. 3A and 3B illustrates two examples of CMOS inverters 310 and 320 serving as threshold-comparing sub-convertors and corresponding transfer function curves 315 and 325. In FIG. 3A, the CMOS inverter 310 comprises a p-type transistor 311 and an n-type transistor 312. The gate of the p-type transistor 311 is coupled to an input voltage signal 313 and the gate of the n-type transistor 312 is coupled to a bias voltage 314. The transfer function curve 315 shows that the voltage threshold is higher than mid-way between the power supply voltage and ground. Based on whether the value of the input voltage signal 313 is greater than the voltage threshold or not, the CMOS inverter 310 can output a logic “1” or “0”. In FIG. 3B, the CMOS inverter 320 comprises a p-type transistor 321 and an n-type transistor 322. The gate of the p-type transistor 321 is coupled to a bias voltage 324 and the gate of the n-type transistor 322 is coupled to the input voltage signal 323. The transfer function curve 325 shows that the voltage threshold is lower than mid-way between the power supply voltage and ground. Based on whether the value of the input voltage signal 323 is greater than the voltage threshold or not, the CMOS inverter 320 can output a logic “0” or “1”. FIG. 3C illustrates an example bias voltage generator 330. When an enable signal 331 is “1”, the bias voltage generator 330 can generate the bias voltages 314 and 324.

FIG. 3D illustrates an example threshold-comparing convertor 340 comprising two threshold-comparing sub-convertors 341 and 342 that have two different thresholds and a corresponding transfer function curve 345. The two threshold-comparing sub-convertors 341 and 342 can be implemented using the CMOS inverters 310 and 320, respectively. As the corresponding transfer function curve 345 shows, the threshold-comparing convertor 340 is equivalent to a 1.5-bit analog-to-digital convertor: outputting one 2-bit code when an input voltage 343 is below a first threshold 346, a second 2-bit code when the input voltage 343 is above the first threshold 346 but less than a second threshold 347, and a third 2-bit code when the input voltage 343 is above the second threshold 347. The first threshold 346 is approximately an NMOS transistor's threshold voltage higher than the reference ground voltage, and the second threshold 347 is approximately a PMOS transistor's threshold voltage lower than the reference power supply voltage.

Threshold-comparing sub-convertors can also be implemented using a logic gate with a voltage threshold that is designed to be at or offset from midrange between the power supply and the ground. Examples of the logic gates include AND gates and multiplexers.

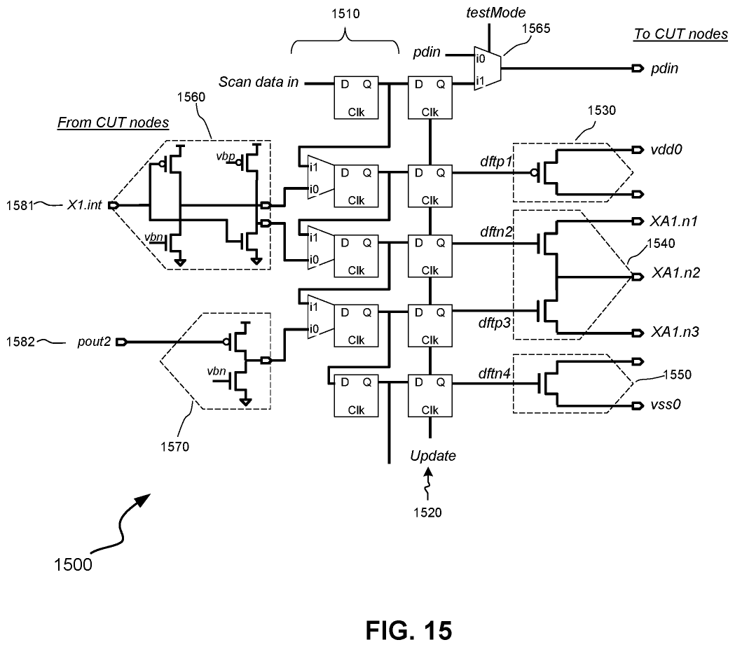

As shown in FIG. 2, the node-connecting devices 231, 232 and 233 comprise two, one and two switching devices, respectively. These switching devices can cause the selected internal nodes 236, 237 and 238 to be either coupled to or decoupled from their associated nodes based on bit values outputted by the one or more scan chains 210. Specifically, a two-bit value 241 enables the selected internal node 236 to be coupled to either a node 242, or a node 243, or none of them; a one-bit value 244 enables the selected internal node 237 to be either coupled to or decoupled from a node 245; and a two-bit value 246 enables the selected internal node 238 to be coupled to either a node 247, or a node 248, or none of them. In addition to selected internal nodes, some circuits may have one or more digital signal nodes like a node 249 selected for applying test pattern bits. Some other circuits may have only digital signal nodes selected for applying test pattern bits. In either of these two cases, test pattern bits stored in the scan chains can be applied to these selected digital signal nodes via digital multiplexers (see an example multiplexer 1565 in FIG. 15) without using node-connecting devices.

It should be noted that while the node-connecting devices 231, 232 and 233 are shown to have at most two switching devices, node-connecting devices may comprise more than two switching devices in some embodiments of the disclosed technology. In some other embodiments of the disclosed technology, each node-connecting device may comprise two switching devices. It should also be noted that the inputs of the node-connecting devices 231, 232 and 233 may be coupled directly or indirectly to parallel outputs of the one or more scan chains 210. In the indirect coupling, update storage elements like the update storage elements 190 in FIG. 1B can be inserted between inputs of the node-connecting devices 231, 232 and 233 and parallel outputs of the one or more scan chains 210.

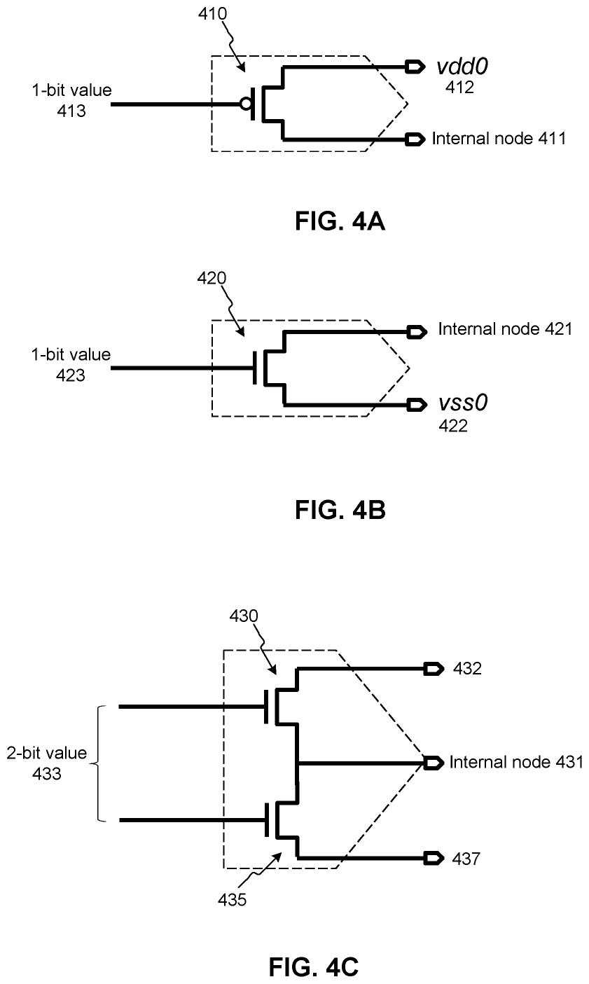

Switching devices in a node-connecting device can be implemented using transistors such as metal-oxide semiconductor field-effect transistors (MOS FETs) according to various embodiments of the disclosed technology. FIGS. 4A, 4B and 4C illustrates three such examples. In FIG. 4A, a transistor 410 can connect an internal node 411 to a power supply node (vdd0) 412 when a 1-bit value 413 at its gate is “0” and disconnect the internal node 411 from the power supply node (vdd0) 412 when the 1-bit value 413 at its gate is “1”. In FIG. 4B, a transistor 420 can connect an internal node 421 to a ground node (vss0) 422 when a 1-bit value 423 at its gate is “1” and disconnect the internal node 421 from the power ground node (vss0) 422 when the 1-bit value 423 at its gate is “0”. While the node 412 is shown to be a power supply node and the node 422 is shown to be a ground node, they can also be any other nodes such as internal nodes.

In FIG. 4C, two transistors 430 and 435 can connect an internal node 431 to either a node 432, or a node 437, or none of them, based on a 2-bit code 433. Each of the nodes 432 and 437 can be a power supply node, a ground node, or another internal node. It should be noted that the two transistors 430 and 435 are typically of the same type, either NMOS or PMOS depending on the circuit, when the nodes 432 and 437 are of the same type, like the drains (or sources) of two transistors in a differential pair, whereas the two transistors 430 and 435 are typically of different types when one of the nodes 432 and 437 is a power supply node and the other is a ground node. It is usually undesirable to simultaneously connect the three nodes 431, 432 and 437 together especially when one of the nodes 432 and 437 is a power supply node and the other is a ground node. Thus the particular value of the 2-bit code 433 enabling it should be avoided. This can be accomplished by adding some circuitry between scan cells and the gates of the switching devices 430 and 435.

In this disclosure, a node is any region of a circuit between two or more circuit elements. In circuit diagrams, connections are ideal wires with zero resistance, so a node is the entire section of wire between elements, not just a single point. An internal node of a circuit is a node connected to none of circuit inputs including power supply and ground and circuit outputs. A digital signal node is a node connected to at least an output or input of a digital circuit element like a logic gate.

The nodes 226, 227 and 228 for observing test responses can be selected based on user specification, circuit topology, or both. A node can be a good candidate for observing test responses if it has impedance low enough that connecting an input of threshold-comparing convertor to it would not affect the circuit's performance. Some examples of such low impedance nodes include outputs of functions and outputs of amplifiers. The IEEE P1687.2 Draft Standard for Test Access and Control provides an Instrument Connectivity Language (ICL) that specifies how to list properties of a circuit's test-related ports. These properties could be used to automatically identify suitable output ports of the circuit.

Similarly, the internal nodes 236, 237 and 238 for applying test stimuli can be selected based on user specification, circuit topology, or both. The number of circuit elements connected to a node, for example, may be used as a criterion for the selection. The more circuit elements that are connected to a node, the more potential defects the node-connecting device could activate. Additionally or alternatively, parameters of a circuit element may serve as criteria. According to various embodiments of the disclosed technology, a transistor's channel width may be considered as well. As an example of user specification, the source or drain of a transistor for which a user wants to add one or more switching devices for enhanced production burn-in testing can be selected as an internal node for applying test stimuli. Amplifiers are common analog devices and often include differential pairs. The common drain or source of a differential pair can be a good candidate as an internal node for applying test stimuli.

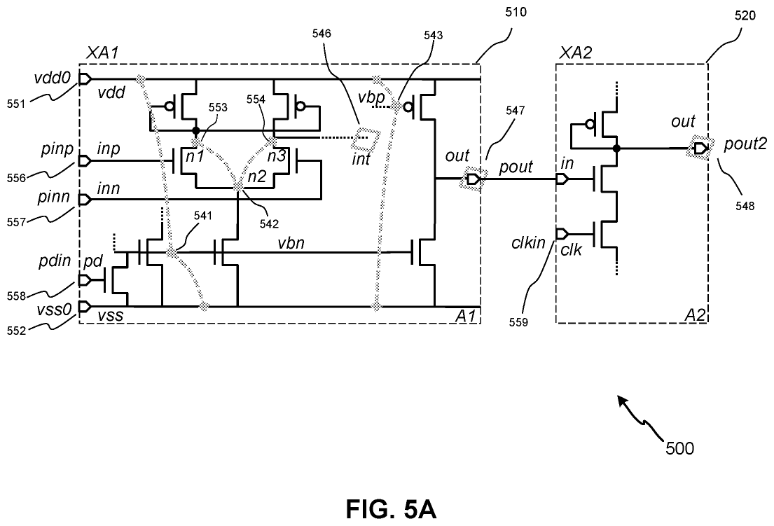

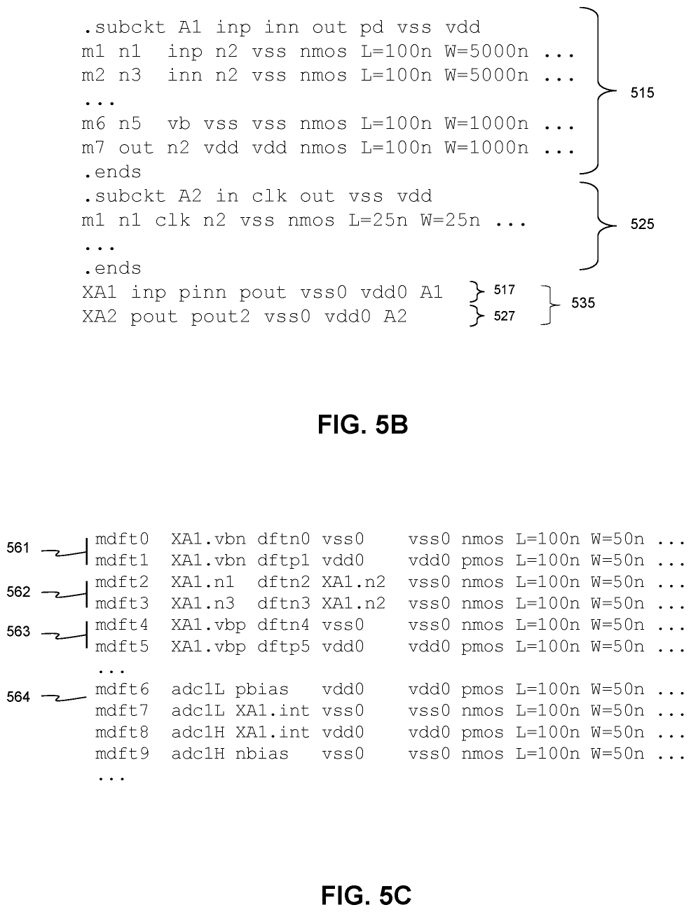

FIG. 5A illustrates an example circuit schematic diagram for a circuit 500 showing some circuit elements, internal circuit nodes selected for applying test stimuli, and circuit nodes selected for test response observation according to various embodiments of the disclosed technology. FIG. 5B illustrates an example netlist for the circuit 500. The circuit 500 includes two subcircuits 510 and 520. The netlist 515 represents the subcircuit 510, the netlist 525 represents the subcircuit 520, and the netlist 535 is a top-level netlist that includes instances 517 and 527 of the two subcircuits 510 and 520. The circuit 500 has function inputs 556 and 557, a power supply input 551, a ground input 552, a power-down input 558, and a clock input 559. The subcircuit 510 has an output 547; and the subcircuit 520 has an output 548.

In the circuit 500, internal nodes 541, 542 and 543 are selected for applying test stimuli; and a node 546 and the outputs 547 and 548 are selected for observing test responses. A node-connecting device comprising two switching devices can be inserted to control connections of the internal node 541 with the power supply node (vdd0) 551 and the ground node (vss0) 552. Similarly, another node-connecting device comprising two switching devices can be inserted to control connections of the internal node 543 with the power supply node (vdd0) 551 and the ground node (vss0) 552. Digitally enabling the connections during testing can increase the voltage swing on more nodes of the circuit 500 than signals applied to the analog inputs such as the inputs 556 and 557 would. This can cause minor flaws in transistor gate oxides to become latent defects that can be more easily detected by subsequent testing.

A third node-connecting device comprising two switching devices can be inserted to control connections of the internal node 542 with an internal node 553 and another internal node 554. Through the internal node 542 and the two associated internal nodes 553 and 554, the equivalent of a small offset voltage can be digitally injected, as a test stimulus, in a differential pair of transistors at the front-end of an operational amplifier. Such amplifiers can have very high gain, so a very small stimulus amplitude is needed to test that the gain is, in fact, high for each manufactured implementation of the circuit. The voltage at the node 547 can be used to check the gain. A threshold-comparing convertor comprising two threshold-comparing sub-convertors like the threshold-comparing convertor 340 shown in FIG. 3D may be employed for the purpose. Similarly, threshold-comparing convertors can be used to convert voltages at the nodes associated with the outputs 547 and 548 to digital test response bits for capturing. The node-connecting devices for injecting test pattern bits at the nodes 541 and 543 may be implemented using the node-connecting device shown in FIG. 4C in which the transistors 430 and 435 are of different types; and the node-connecting device for injecting test pattern bits at the node 542 may be implemented using the node-connecting device shown in FIG. 4C in which the transistors 430 and 435 are both NMOS. FIG. 5C illustrates example netlists 561, 562 and 563 for the three node-connecting devices and an example netlist 564 for the threshold-comparing convertor coupled to the node 547. The netlists 561, 562, 563 and 564 along with netlists for the threshold-comparing convertors coupled to the nodes 547 and 548 would be added to the top-level netlist.

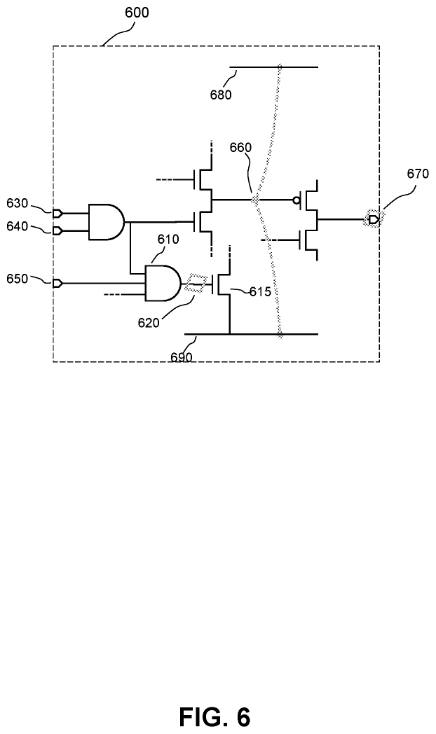

FIG. 6 illustrates an example circuit schematic diagram for a circuit 600 comprising both analog and digital circuitry. The digital circuitry includes logic gates such as an AND gate 610. An output 620 of the AND gate 610 directly drives an analog transistor 615. Such an output node 620 has low impedance and thus can be selected for observing test responses. A threshold-comparing convertor with a midrange threshold can be employed for the purpose. Some or all of digital signal inputs 630, 640 and 650 (digital signal nodes) can be selected for injecting test pattern bits in test mode via digital multiplexers. No node-connecting device is needed. An internal node 660 can also be selected for injecting test pattern bits. A node-connecting device can be inserted to connect the internal node 660 to either a power supply node 680 or a ground node 690, and to disconnect the internal node 660 from both the supply node 680 and the ground node 690. An output node 670 can be selected for observing test responses as well. A threshold-comparing convertor can be employed for the purpose.

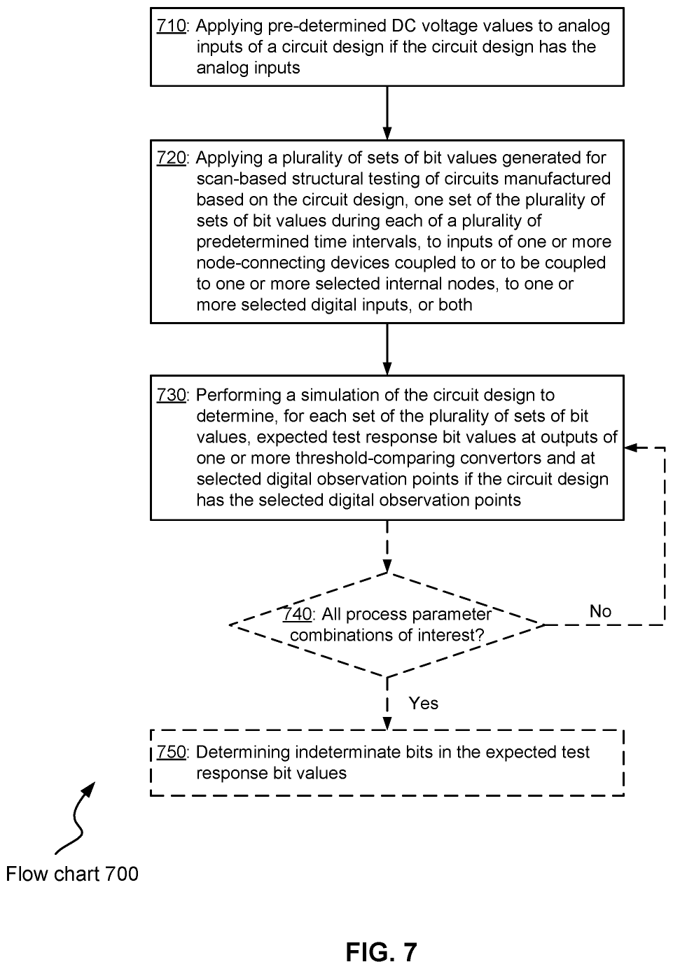

FIG. 7 illustrates a flowchart 700 showing a process of determining good-circuit (or expected) test responses for test patterns based on simulating a defect-free analog/mixed-signal circuit design that may be implemented according to various examples of the disclosed technology. For ease of understanding, methods for simulating a defect-free analog/mixed-signal circuit design to determine good-circuit test responses for test patterns that may be employed according to various embodiments of the disclosed technology will be described with reference to the circuit 500 shown in FIG. 5A and the flow chart 700 illustrated in FIG. 7. It should be appreciated, however, that the methods for simulating a defect-free analog/mixed-signal circuit design to determine good-circuit test responses for test patterns illustrated by the flow chart 700 can be applied to an analog/mixed-signal circuit design different from the circuit 500 in FIG. 5A according to various embodiments of the disclosed technology. Likewise, the circuit 500 may be simulated using other methods for simulating a defect-free analog/mixed-signal circuit design to determine good-circuit test responses for test patterns according to various embodiments of the disclosed technology.

In operation 710, pre-determined DC voltage values are applied to analog inputs of a circuit design if the circuit design has the analog inputs. The circuit design may be a whole circuit design or a portion of a circuit design such as a core or a circuit block in a circuit design. The circuit design is at least partially analog. Analog circuitry works with analog signals. An analog signal is a continuously variable signal as opposed to a digital signal made up of binary ups and downs (or pulses). With various implementations of the disclosed technology, the pre-determined DC voltage values may be set to be in the midrange of voltage values that would be applied to the analog inputs during the circuit's normal operation.

The circuit 500 has two analog function inputs 556 and 557. The range of voltage values that would be applied to them during the circuit's normal operation is between 0 and 3.0 volts. Accordingly, the pre-determined DC voltage values for the two analog function inputs 556 and 557 can be set to be 1.5 volts. The circuit 500 also has a clock input 559. A periodic clock signal at the nominal frequency of the clock input 559 can be applied to it. In addition to the clock input, some digital inputs such as reset signals may need to be treated specially. In the circuit 500, for example, a power-down signal for the power-down input 558 can be in its power-up mode for most test patterns and in power-down mode for at least some test patterns.

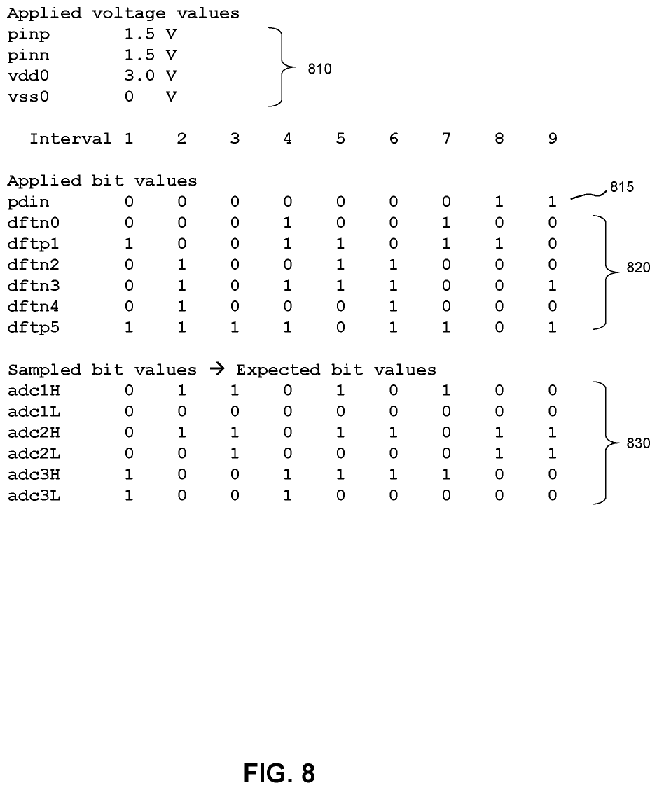

FIG. 8 illustrates an example of voltages applied to the analog inputs of the circuit 500. A block 810 titled “Applied voltage values” shows that the voltages at the analog function inputs 556 and 557, the power supply input 551, and the ground input 552 are 1.5, 1.5, 3.0 and 0 volts, respectively. A row 815 titled “pdin” shows the bit value at the power-down input 558, a specially-treated digital signal input. The bit value is “0” and the circuit 500 is in the power-up mode during the first seven time intervals; and the bit value is “1” and the circuit 500 is in the power-down mode during the last two time intervals.

Referring back to FIG. 7, in operation 720, a plurality of sets of bit values are applied, one set of the plurality of sets of bit values during each of a plurality of consecutive time intervals, to inputs of one or more node-connecting devices coupled to or to be coupled to one or more selected internal nodes, to one or more selected digital inputs, or both. The one or more selected internal nodes and the one or more selected digital inputs can be selected based on user specification, circuit topology, or both. The number of circuit elements connected to an internal node, for example, may be used as a criterion for the selection of internal nodes. Additionally or alternatively, parameters of a circuit element may serve as criteria. According to various embodiments of the disclosed technology, a transistor's width may be considered as well.

Each of the one or more node-connecting devices is configured to at least cause one of the one or more selected internal nodes to be either coupled to or decoupled from another node of the circuit (a node associated with the one of the one or more selected internal nodes) based on bit values at inputs of the each of the one or more input node-connecting devices. To perform the function, each of the one or more node-connecting devices can comprise one or more switching devices like the node-connecting devices 231, 232 and 233 in FIG. 2. The switching devices can be implemented using transistors such as metal-oxide semiconductor field-effect transistors like the transistors 410, 420, 430 and 435 shown in FIGS. 4A-C. The circuit 500 can use two node-connecting devices to control the connections of the internal node 541 and the internal node 543 with the power supply node (vdd0) 551 and the ground node (vss0) 552, and a third node-connecting device to control the connection of the internal node 542 with the two associated internal nodes 553 and 554.

The plurality of sets of bit values applied as test stimuli are generated for scan-based structural testing of circuits manufactured based on the circuit design. The plurality of sets of bit values may be generated based on random combinations of bit values or all combinations of bit values for the inputs of the one or more node-connecting devices if the circuit design has the one or more selected internal nodes and for the one or more selected digital inputs if the circuit design has the one or more selected digital inputs. A pseudo-random pattern generator, such as a linear feedback shift register (LFSR) circuit or a software routine, may be employed for the random generation approach. According to various embodiments of the disclosed technology, the first set of bit values applied may be set to be the one that does not cause the one or more selected internal nodes to be coupled to their associated nodes. The defects that could be detected by this set of bit values can be considered as the ones detectable without adding any node-connecting devices. This can serve as a good reference because it is the circuit starting in a normal functional condition.

Each of the plurality of consecutive time intervals is equal to one or more clock cycles of a scan clock signal for the scan-based structural testing of circuits manufactured based on the circuit design. If the circuit design has a circuit's clock signal, each of the plurality of consecutive time intervals is also equal to one or more cycles of the circuit's clock signal. The time interval can begin when the circuit's clock signal rises, or when it falls—the choice of edge can be based on when the input signals to the circuit design are sampled by the circuit's clock signal, and when the outputs of the circuit design change. For example, if circuit nodes are initialized when the circuit's clock signal is logic 0, and output signals change shortly after the circuit's clock signal rises to logic 1, then each of the plurality of sets of bit values can be applied when the circuit's clock signal falls to logic 0. The time interval can be set to be large enough that all signals in the circuit design have settled to a constant value in the time interval so that the resulting circuit design output values will be more independent of the sequence of the plurality of sets of bit values, as is done typically for digital automatic test pattern generation (ATPG). This can allow plurality of sets of bit values to be reduced more which will be discussed later.

FIG. 8 also illustrates an example of nine sets of bit values 820 applied as test stimuli to the circuit 500 at nine consecutive time intervals. The first two rows “dftn0” and “dftp1” in the nine sets of bit values 820 represent bit values at the inputs of the NMOS and PMOS transistors coupled to the internal node 541; the next two rows “dftn2” and “dftn3” represent bit values at the inputs of the two NMOS transistors coupled to the internal node 542; and the last two rows “dftn4” and “dftp5” represent bit values at the inputs of the NMOS and PMOS transistors coupled to the internal node 543. The nine sets of bit values 820 are randomly generated except the bit values for the first time interval. During the first time interval, the bit values are logic ‘0’ for each NMOS transistor gate and logic ‘1’ for each PMOS transistor gate. These bit values would not enable the transistors to convey current and thus decouple the internal nodes 541, 542 and 543 from their associated nodes. As such, the circuit 500 operates in a normal functional state just like the one with no node-connecting devices added during the first time interval.

Referring back to FIG. 7, in operation 730, a simulation of the circuit design is performed to determine, for each set of the plurality of sets of bit values, expected test response bit values at outputs of one or more threshold-comparing convertors and at selected digital signal nodes if the circuit design has the selected digital signal nodes. Each of the one or more threshold-comparing convertors is coupled to or to be coupled to one of one or more selected nodes of the circuit design. Like the threshold-comparing convertors 221, 222 and 223 in FIG. 2, each of the one or more threshold-comparing convertors comprises one or more threshold-comparing sub-convertors, and each of the one or more threshold-comparing sub-convertors is configured to output a bit value at one of outputs of the each of the one or more threshold-comparing convertors based on comparing a voltage value at the one of one or more selected nodes with one preset threshold. If a threshold-comparing convertor comprises only one threshold-comparing sub-convertor, the preset threshold may be set at the midpoint of the voltage range for the selected node. If a threshold-comparing convertor comprises two threshold-comparing sub-convertors, one preset threshold may be set above the midpoint of the voltage range for the selected node and the other preset threshold below it, similar to the thresholds 346 and 347 in FIG. 3D. The one or more threshold-comparing sub-convertors can be implemented using CMOS inverters, logic gates or other devices.

The one or more selected nodes coupled to the one or more threshold-comparing convertors can also be selected based on user specification, circuit topology, or both. As noted previously, a node can be a good candidate for observing test responses if it has impedance low enough that connecting an input of threshold-comparing convertor to it would not affect the circuit's performance. Some examples of such low impedance nodes include outputs of functions and outputs of amplifiers.

To perform simulations of the defect-free circuit design for the plurality of sets of bit values, neither the one or more node-connecting devices nor the one or more threshold-comparing convertors need to be inserted into the circuit design, at least in the early stages of design for test process. Simulating a defect-injected circuit design, which will be discussed in detail later, can identify, in the one or more node-connecting devices, the one or more threshold-comparing convertors, or both, some circuitry unnecessary for defect detection. Accordingly, the node-connecting devices and threshold-comparing convertors eventually inserted into the circuit design may be different from those chosen initially. With various implementations of the disclosed technology, an ideal switch can be added in place of a switching device in a node-connecting device with ‘on’ and ‘off’ resistances similar to that of the replaced switching device. Voltages at the one or more selected nodes for observing test responses can be sampled and then compared to the one or more preset thresholds to determine the expected test response bit values without inserting threshold-comparing convertors into the circuit design. Similar to how sets of bit values are applied to and test response bit values are captured from digital combinational logic, voltages at the one or more selected nodes for observing test responses can be sampled just before each set change in the plurality of sets of bit values.

In the circuit 500, the node 546 and the outputs 547 and 548 are selected as the nodes for observing test responses, and each of the threshold-comparing convertors employed comprises two threshold-comparing sub-convertors like the threshold-comparing convertor 340 in FIG. 3D. FIG. 8 further illustrates expected test response bit values 830 captured during the nine consecutive time intervals obtained based on the simulation of the circuit 500. The first two rows “adc1H” and “adc1L” of the expected test response bit values 830 represent bit values at the outputs of the threshold-comparing sub-convertor coupled to the node 546; the next two rows “adc2H” and “adc2L” represent bit values at the outputs of the threshold-comparing sub-convertor coupled to the output 547; and the last two rows “adc3H” and “adc3L” represent bit values at the outputs of the threshold-comparing sub-convertor coupled to the output 548.

Referring back to FIG. 7, an optional operation 740 determines whether the simulation is performed for all process parameter combinations of interest. Typically, a circuit is designed to pass all its function tests for any combination of process parameters values that is within the manufacturing process's specifications. The circuit design can be first simulated with the typical value for each of the circuit element model process parameter values. Then, the circuit design can be simulated with different combinations of various process parameter values. After the process is finished, in operation 750, indeterminate bits in the expected test response bit values are identified. An indeterminate bit in this operation is a bit that has different values for different combinations of the process parameter values, which can be set to be “X”.

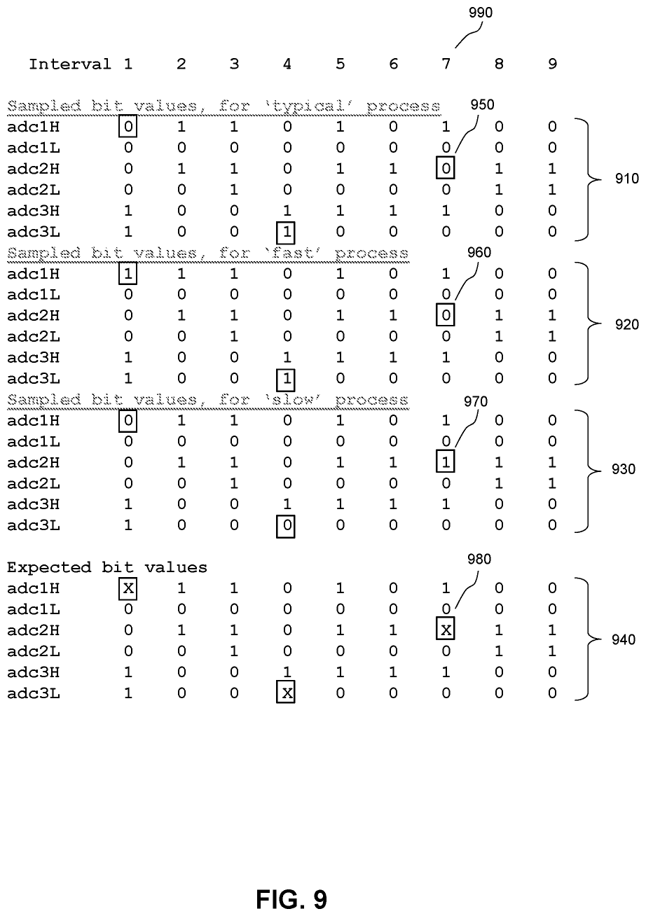

FIG. 9 illustrates an example for determining indeterminate bits in the expected test response bit values for the circuit 500. The simulation of the circuit 500 is performed under a “typical” set of process parameter values, a “worst” or “slow” set of process parameter values, and a “best” or “fast” set of process parameter values, respectively. FIG. 9 lists expected test response bit values 910, 920 and 930 for the three sets of process parameter values captured during the nine consecutive time intervals and final expected test response bit values 940 derived based on them. By comparing the expected test response bit values 910, 920 and 930, three indeterminate bits are identified and set as “X” in the final expected test response bit values 940. For example, during the seventh time interval 990, the test response bits 950, 960 and 970 outputted from the output of the threshold-comparing convertor associated with the node 547 (labeled as “adc2H” in the figure) are “0”, “0”, and “1”, respectively. An “X” is assigned to be the corresponding bit value 980 in the final expected test response bit values 940.

In addition to handling explicit process parameter variations, a voltage margin may be added around a preset threshold used by a threshold-comparing sub-convertor to account for additional noise or process variations. If a voltage value at a selected node for observing test responses is within a preset range centered at the preset threshold, the corresponding test response bit value can be set as “X”. For example, if a node's voltage samples range from 1.1 to 1.3 volts for different process parameter values, and the threshold voltage is 1.0 volts, and the added margin is 0.2 volts, then the expected logic value for that sample can be set to ‘X’ because 1.1 is within the 0.2 volt margin around 1.0 volts.

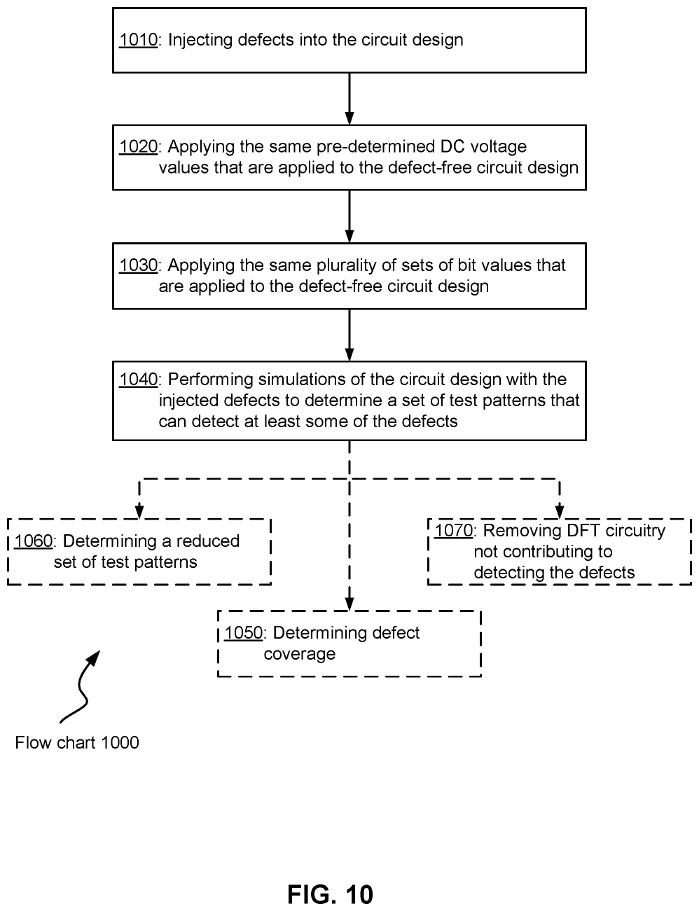

The result of the process illustrated by the flow chart 700 is a time sequence of test patterns (the plurality sets of bit values) and their expected test response bit values. In addition to simulating the defect-free circuit design, the automatic test pattern generation process may further comprise simulating a plurality of defect-injected analog/mixed-signal circuit designs. FIG. 10 illustrates a flowchart 1000 showing a process of simulating a plurality of defect-injected analog/mixed-signal circuit designs according to various embodiments of the disclosed technology. For ease of understanding, methods for simulating a plurality of defect-injected analog/mixed-signal circuit designs that may be employed according to various embodiments of the disclosed technology will be described with reference to the circuit 500 shown in FIG. 5A and the flow chart 1000 illustrated in FIG. 10. It should be appreciated, however, that the methods for simulating a plurality of defect-injected analog/mixed-signal circuit designs illustrated by the flow chart 1000 can be applied to an analog/mixed-signal circuit design different from the circuit 500 in FIG. 5A according to various embodiments of the disclosed technology. Likewise, the circuit 500 may be simulated using other methods for simulating a plurality of defect-injected analog/mixed-signal circuit designs according to various embodiments of the disclosed technology.

In operation 1010, defects are injected into the circuit design. Two common types of defects for analog or mixed-signal circuits are open defects and short defects. The latter are also referred to as bridge defects. The defect injection sites can be determined based on user specification, circuit topology, or both. According to various embodiments of the disclosed technology, the defects can be injected into the circuit design one at a time for simulation.

The next two operations in the flow chart 1000 are similar to the operations 710 and 720 in the flow chart 700. In operation 1020, the same pre-determined DC voltage values used in the operation 710 are applied to the analog inputs of the defect-injected circuit design if the circuit design has the analog inputs. In operation 1030, the same plurality of sets of bit values used in the operation 720 are applied to the inputs of the one or more node-connecting devices coupled to or to be coupled to the one or more selected internal nodes, to the one or more selected digital inputs, or both. Here, the plurality of sets of bit values are applied not only as one set during each of the plurality of consecutive time intervals but also in the same sequence as they are applied to the defect-free circuit design.

In operation 1040, simulations of the defects-injected circuit design are performed to determine a set of test patterns that can detect at least some of the defects. For each of the simulations, test response bit values derived are compared with the corresponding expected test response bit values derived from simulating the defect-free circuit design. If the expected test response bit value is ‘X’, the comparison is not performed. If at least one of the test response bit values is different from the corresponding expected test response bit value, the injected defect(s) can be declared detected. In optional operation 1050, defect coverage that measures the number of defects detectable by the set of test patterns vs the total number of defects is determined. If the determined defect coverage is not high enough, the plurality of sets of bit values, the selected internal nodes for test stimuli injection, the selected nodes for test response observation, or any combination thereof may be adjusted.

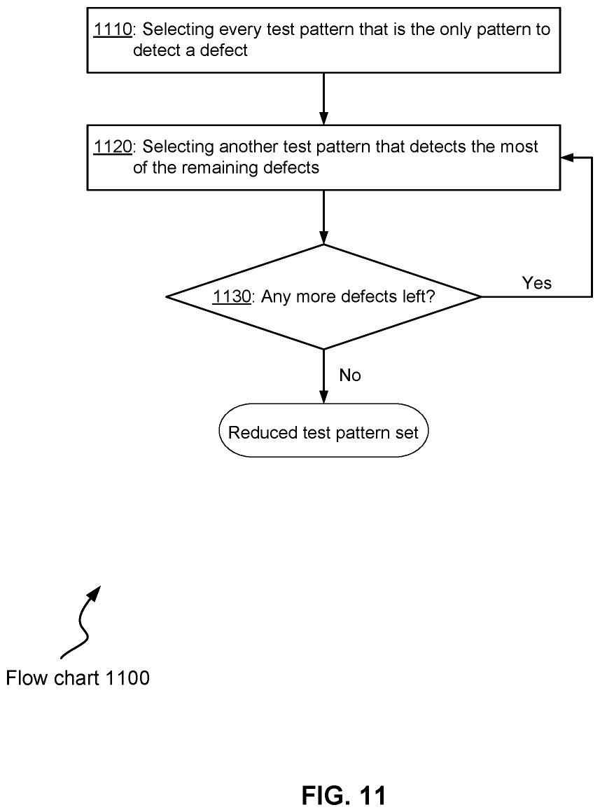

The set of test patterns may be obtained by selecting all sets of bit values that detect defects not detected by any other set of bit values. The set of test patterns can be compacted without compromising the defect coverage. In optional operation 1060, a reduced set of test patterns that can detect the same defects as the set of test patterns is determined. To choose a minimum number of test patterns, a digital automatic test pattern generation (ATPG) minimization algorithm or a greedy algorithm can be used. FIG. 11 illustrates a flowchart 1100 showing a process of using a greedy algorithm to derive a reduced set of test patterns according to various embodiments of the disclosed technology. In operation 1110, every test pattern that is the only pattern to detect a defect is selected. In operation 1120, another test pattern that detects the most of the remaining defects is selected. In operation 1130, the process checks whether there are any defects left. If the answer is yes, the operations 1120 and 1130 are repeated by selecting another test pattern. These selection and check operations continue until the selected test patterns can detect all of the defects detected by the original set of test patterns.

Sometimes a short sequence of consecutive test patterns may need to be retained even if only the last test pattern in the short sequence detects the defects. This is due to dependency on previous values for the last test pattern. Without using the short sequences of consecutive test patterns, test consistency between the original set of test patterns and the reduced set of test patterns can suffer. Retaining short sequences can also allow the time interval between consecutive test patterns to be reduced so that some signals intentionally do not have time to settle and the sampled node voltages become sensitive to the values of resistances and capacitances. In many types of analog circuits, such as switched-capacitor filters, settling times and signal propagation delays are longer than the period of the highest frequency clock applied to the circuit. Also, some transistors might not conduct any current during some applied test patterns which will cause some node voltages to drift up or down due to leakage current, and this will make the output voltages for the immediately following combination of logic values depend on the preceding combination.

A short sequence of test patterns can be two, three, or more consecutive test patterns. In any case, the expected logic values for all but the last test pattern in each selected short sequence can be set to ‘X’ because the test pattern might be preceded by different test patterns in the reduced set of test patterns than in the original set of test patterns.

Referring back to FIG. 10, in optional operation 1070, testing circuitry not uniquely contributing to detecting the defects is removed. If a bit value that controls a switching device in a node-connecting device is always the same value that does not enable the switching device, then the switching device can be removed since it does not uniquely contribute to detecting any defect. If a threshold-comparing sub-convertor in a threshold-comparing convertor outputs a bit value that does not uniquely contribute to detecting any defect, then the threshold-comparing sub-convertor can be removed. This operation may be performed after the optional operation 1060. The reduced set of test patterns obtained may lead to more testing circuitry being removed than based on the original set of the test patterns.

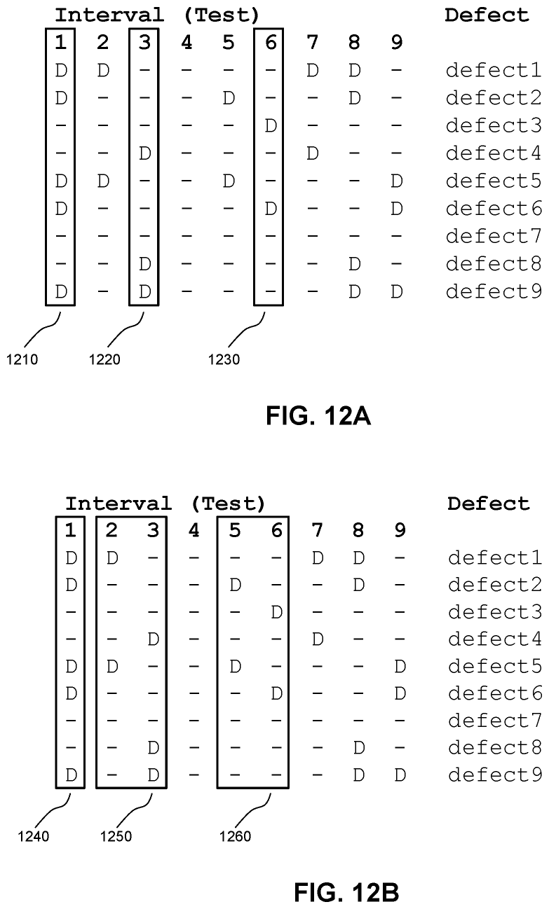

FIG. 12A illustrates an example defect detection matrix for nine defects of the circuit 500 detected using nine sets of bit values (test patterns) applied during the nine consecutive time intervals. Each row indicates a result for a different defect. The letter “D” indicates the defect of interest is detected. Based on the greedy algorithm illustrated in FIG. 11, the test pattern applied during the time interval 1230 is selected first because it is the only pattern to detect defect3. The test pattern applied during the time interval 1210 is the one that detects the most of the remaining defects and is thus selected second. The test pattern applied during the time interval 1220 detects the remaining defects and is selected third and also last. A reduced set of the three test patterns applied during the time intervals 1210, 1220 and 1230 is formed. The detect coverage is not impacted.

FIG. 12B illustrates an example of forming a reduced set of short sequences of test patterns. If short sequences of two test patterns are needed to keep test consistency, for example, the test patterns immediately preceding those applied during the time intervals 3 and 6 will be retained, forming two short sequences 1250 and 1260. Since the time interval 1 is the first time interval and has no preceding time interval other than the initial conditions of indefinite duration, its short sequence 1240 contains only one test pattern.

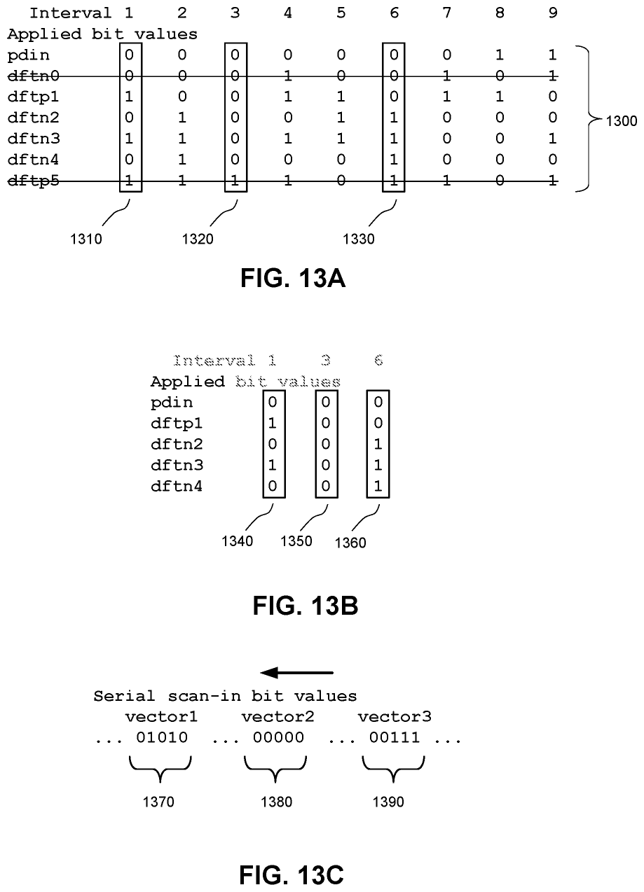

FIG. 13A shows a set of test patterns 1300 applied to the circuit 500 during all of the nine consecutive time intervals. Three test patterns 1310, 1320, and 1330 outlined correspond to the test patterns applied during the time intervals 1210, 1220 and 1230 identified to be associated with the reduced set of test patterns in FIG. 12A. When only this reduced set of test patterns 1310, 1320, and 1330 is considered, the NMOS transistor (dftn0) is driven always by a signal of “0” while the PMOS transistor (dftp5) is driven always by a signal of “1”. As such, they are never enabled and these rows of the set of test patterns 1300 can be crossed out and the NMOS transistor (dftn0) and the PMOS transistor (dftp5) can be removed without affecting the test coverage. FIG. 13B illustrates a reduced set of test patterns 1340, 1350, and 1360, for time intervals 1, 3 and 6, and without the rows for the NMOS transistor (dftn0) and the PMOS transistor (dftp5). FIG. 13C shows how the test patterns 1340, 1350, and 1360 might be shifted in as 1370, 1380, and 1390, respectively, in a serial bit stream applied to a scan chain.

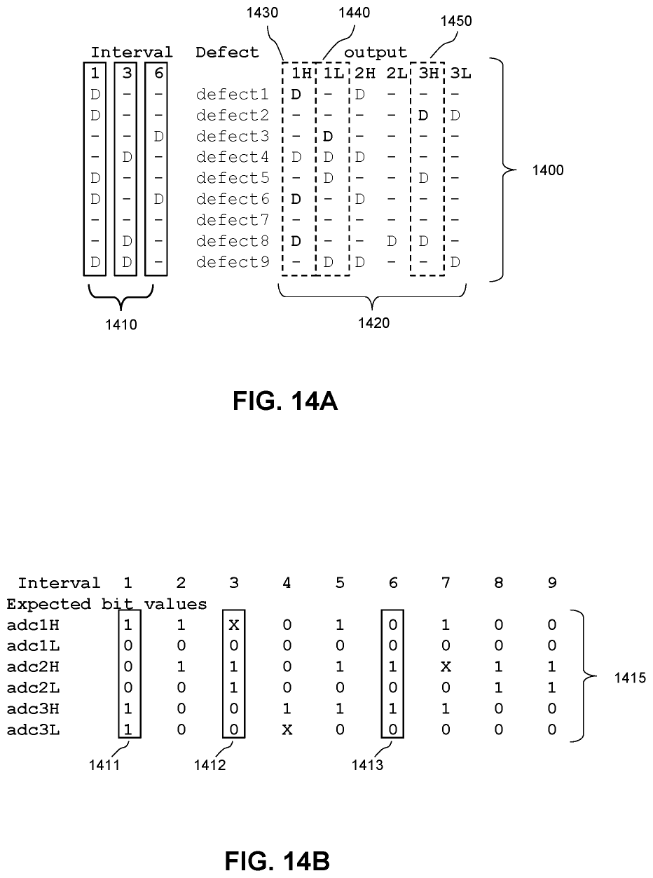

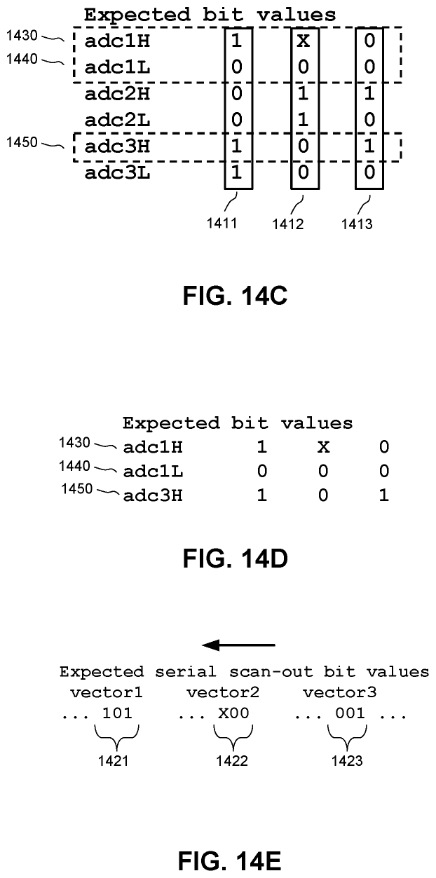

FIG. 14A illustrates an example defect detection matrix 1400 for the circuit 500 in terms of both the reduced set of test pattern bit locations 1410 (corresponding to the time intervals 1210, 1220 1230 of the defect detection matrix in FIG. 12A) and test response bit locations 1420. As noted previously, each of the three threshold-comparing convertors has two threshold-comparing sub-convertors, one using a high threshold (“H”) and the other using a low threshold (“L”), and thus can output two bit values. The threshold-comparing sub-convertors 1430, 1440 and 1450 can be selected, and the rest of the threshold-comparing sub-convertors can be removed since they do not detect defects uniquely. FIG. 14B shows an example of expected test response bit values for each of the threshold-comparing sub-convertors for the nine consecutive time intervals with the reduced set of test patterns in intervals 1, 3, and 6 outlined as 1411, 1412, and 1413. FIG. 14C shows the expected test response bit values only for the time intervals 1411, 1412 and 1413 associated with the reduced set of test patterns. FIG. 14D shows the minimized set of expected test response bit values only for the threshold-comparing sub-convertors 1430, 1440 and 1450. FIG. 14E shows how the minimized set of expected test response bit values might be shifted out as 1421, 1422, and 1423 along a scan chain.

In some cases, some or all of the switching devices in node-connecting devices that are not needed to achieve maximum defect coverage may not be removed because they could be deemed useful for diagnosing defects. Similarly, some or all of the threshold-comparing sub-convertors in threshold-comparing convertors that are not needed to achieve maximum defect coverage may not be removed because they could be deemed useful for diagnosing defects.

FIG. 15 illustrates an example of test circuitry 1500 for the circuit 500. The test circuitry 1500 comprises a scan chain 1510 and associated update register 1520. The test circuitry 1500 also comprises three node-connecting devices 1530, 1540 and 1550 with inputs coupled to the update register 1520 and outputs coupled to the three selected internal nodes of the circuit 500 and their associated nodes. Here the node-connecting devices 1530 and 1550 have only one switching device due to the reduction of test circuitry as illustrated in FIGS. 13A and 13B. The test circuitry 1500 further comprises two threshold-comparing convertors 1560 and 1570 for observing test responses at the two selected nodes 1581 (X1.int) and 1582 (pout2). According to FIG. 14A-D, neither test responses at another originally selected node 547 (pout) in the circuit 500 nor the low-threshold test response bits for the node 1582 detects defects uniquely. Therefore, there is no threshold-comparing convertor for the originally selected node 547 (pout) and the threshold-comparing convertor 1570 has only one threshold-comparing sub-convertor using a high threshold.

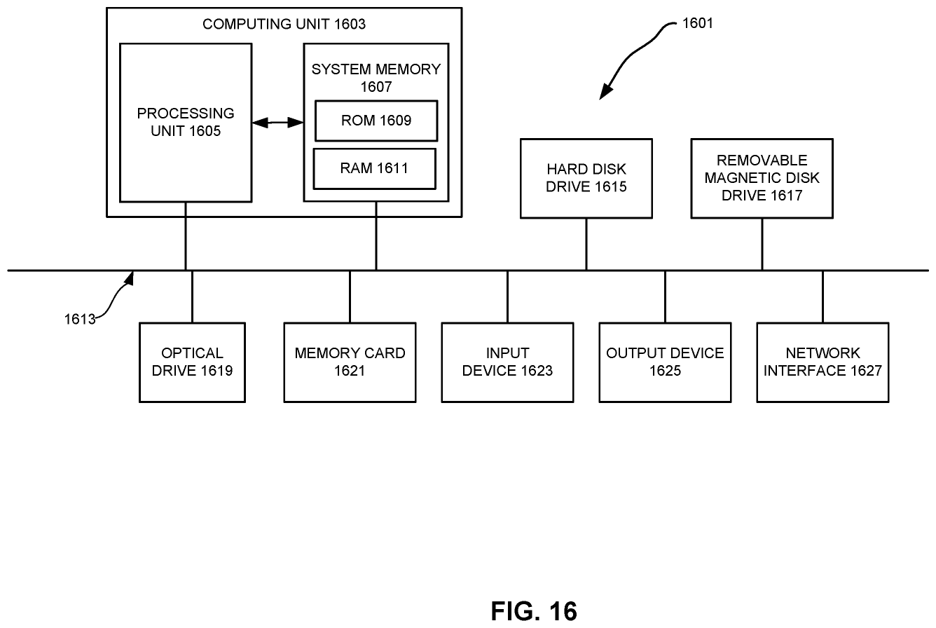

Various examples of the disclosed technology may be implemented through the execution of software instructions by a computing device, such as a programmable computer. Accordingly, FIG. 16 shows an illustrative example of a computing device 1601. As seen in this figure, the computing device 1601 includes a computing unit 1603 with a processing unit 1605 and a system memory 1607. The processing unit 1605 may be any type of programmable electronic device for executing software instructions, but it will conventionally be a microprocessor. The system memory 1607 may include both a read-only memory (ROM) 1609 and a random access memory (RAM) 1611. As will be appreciated by those of ordinary skill in the art, both the read-only memory (ROM) 1609 and the random access memory (RAM) 1611 may store software instructions for execution by the processing unit 1605.

The processing unit 1605 and the system memory 1607 are connected, either directly or indirectly, through a bus 1613 or alternate communication structure, to one or more peripheral devices. For example, the processing unit 1605 or the system memory 1607 may be directly or indirectly connected to one or more additional memory storage devices, such as a “hard” magnetic disk drive 1615, a removable magnetic disk drive 1617, an optical disk drive 1619, or a flash memory card 1621. The processing unit 1605 and the system memory 1607 also may be directly or indirectly connected to one or more input devices 1623 and one or more output devices 1625. The input devices 1623 may include, for example, a keyboard, a pointing device (such as a mouse, touchpad, stylus, trackball, or joystick), a scanner, a camera, and a microphone. The output devices 1625 may include, for example, a monitor display, a printer and speakers. With various examples of the computing device 1601, one or more of the peripheral devices 1615-1625 may be internally housed with the computing unit 1603. Alternately, one or more of the peripheral devices 1615-1625 may be external to the housing for the computing unit 1603 and connected to the bus 1613 through, for example, a Universal Serial Bus (USB) connection.

With some implementations, the computing unit 1603 may be directly or indirectly connected to one or more network interfaces 1627 for communicating with other devices making up a network. The network interface 1627 translates data and control signals from the computing unit 1603 into network messages according to one or more communication protocols, such as the transmission control protocol (TCP) and the Internet protocol (IP). Also, the network interface 1627 may employ any suitable connection agent (or combination of agents) for connecting to a network, including, for example, a wireless transceiver, a modem, or an Ethernet connection. Such network interfaces and protocols are well known in the art, and thus will not be discussed here in more detail.

It should be appreciated that the computing device 1601 is illustrated as an example only, and it is not intended to be limiting. Various embodiments of the disclosed technology may be implemented using one or more computing devices that include the components of the computing device 1601 illustrated in FIG. 16, which include only a subset of the components illustrated in FIG. 16, or which include an alternate combination of components, including components that are not shown in FIG. 16. For example, various embodiments of the disclosed technology may be implemented using a multi-processor computer, a plurality of single and/or multiprocessor computers arranged into a network, or some combination of both.

### CONCLUSION

Having illustrated and described the principles of the disclosed technology, it will be apparent to those skilled in the art that the disclosed embodiments can be modified in arrangement and detail without departing from such principles. In view of the many possible embodiments to which the principles of the disclosed technologies can be applied, it should be recognized that the illustrated embodiments are only preferred examples of the technologies and should not be taken as limiting the scope of the disclosed technology. Rather, the scope of the disclosed technology is defined by the following claims and their equivalents. We therefore claim as our disclosed technology all that comes within the scope and spirit of these claims.

1. A method, executed by at least one processor of a computer, comprising:
applying pre-determined DC voltage values to analog inputs of a circuit design if the circuit design has the analog inputs, the circuit design being at least partially analog;
applying a plurality of sets of bit values generated for scan-based structural testing of circuits manufactured based on the circuit design, one set of the plurality of sets of bit values during each of a plurality of consecutive time intervals, to inputs of one or more node-connecting devices coupled to or to be coupled to one or more selected internal nodes of the circuit design, to one or more selected digital inputs of the circuit design, or both, each of the one or more node-connecting devices configured to at least cause one of the one or more selected internal nodes to be either coupled to or decoupled from another node of the circuit based on bit values at inputs of the each of the one or more input node-connecting devices, each of the plurality of consecutive time intervals being equal to one or more clock cycles of a scan clock signal for the scan-based structural testing of circuits; and
performing a simulation of the circuit design to determine, for each set of the plurality of sets of bit values, expected test response bit values at outputs of one or more threshold-comparing convertors and at selected digital signal nodes if the circuit design has the selected digital signal nodes, each of the one or more threshold-comparing convertors being coupled to or to be coupled to one of one or more selected nodes of the circuit design and comprising one or more threshold-comparing sub-convertors, each of the one or more threshold-comparing sub-convertors configured to output a bit value at one of outputs of the each of the one or more threshold-comparing convertors based on comparing a voltage value at the one of one or more selected nodes with one of one or more preset thresholds,
wherein in the scan-based structural testing of circuits, at least some bits of the plurality of sets of bit values are applied to each of the circuits using one or more scan chains in the each of the circuits and test response bit values at at least some of the outputs of the one or more threshold-comparing convertors are captured by the one or more scan chains.

2. The method recited in claim 1, wherein the bit value outputted by the each of the one or more threshold-comparing sub-convertors is treated as being indeterminate if the voltage value at the one of one or more selected nodes is within a preset range centered at the one of the one or more preset thresholds.

3. The method recited in claim 1, wherein the bit value outputted by the each of the one or more threshold-comparing sub-convertors is treated as being indeterminate if the performing a simulation is repeated for different combinations of process parameter values and the bit value is not the same for all of the different combinations of process parameter values.

4. The method recited in claim 1, wherein the plurality of sets of bit values are generated based on random combinations of bit values or all combinations of bit values.

5. The method recited in claim 1, wherein the one or more selected internal nodes and the one or more selected nodes are selected based on user specification, circuit topology, or both.

6. The method recited in claim 1, wherein the number of bit values at inputs of the each of the one or more input node-connecting devices is either 1 or 2 and each of at least some of the one or more node-connecting devices is configured to cause, based on a 2-bit value, a selected internal node to be coupled to either or neither of two other nodes of the circuit.

7. The method recited in claim 1, wherein each of the one or more threshold-comparing sub-convertors is implemented by an inverter and each of the one or more threshold-comparing convertors comprises at most two threshold-comparing sub-convertors.

8. The method recited in claim 1, further comprising:
injecting defects into the circuit design; and
performing the operations recited in claim 1 to determine a set of test patterns that can detect at least some of the defects.

9. The method recited in claim 8, wherein the defects are injected into the circuit design one at a time for simulation.

10. The method recited in claim 8, further comprising:
determining a reduced set of test patterns that can detect the at least some of the defects based on the set of test patterns.

11. The method recited in claim 10, wherein the reduced set of test patterns keep some consecutive test patterns in the set of test patterns.

12. The method recited in claim 10, wherein the determining a reduced set of test patterns employs a greedy algorithm.

13. The method recited in claim 8, further comprising:
removing switching devices in the one or more node-connecting devices not uniquely contributing to detecting the defects, threshold-comparing sub-convertors in the one or more threshold-comparing convertors not uniquely contributing to detecting the defects, or both.

14. One or more non-transitory computer-readable media storing computer-executable instructions for causing one or more processors to perform a method, the method comprising:
applying pre-determined DC voltage values to analog inputs of a circuit design if the circuit design has the analog inputs, the circuit design being at least partially analog;
applying a plurality of sets of bit values generated for scan-based structural testing of circuits manufactured based on the circuit design, one set of the plurality of sets of bit values during each of a plurality of consecutive time intervals, to inputs of one or more node-connecting devices coupled to or to be coupled to one or more selected internal nodes of the circuit design, to one or more selected digital inputs of the circuit design, or both, each of the one or more node-connecting devices configured to at least cause one of the one or more selected internal nodes to be either coupled to or decoupled from another node of the circuit based on bit values at inputs of the each of the one or more input node-connecting devices, each of the plurality of consecutive time intervals being equal to one or more clock cycles of a scan clock signal for the scan-based structural testing of circuits; and
performing a simulation of the circuit design to determine, for each set of the plurality of sets of bit values, expected test response bit values at outputs of one or more threshold-comparing convertors and at selected digital signal nodes if the circuit design has the selected digital signal nodes, each of the one or more threshold-comparing convertors being coupled to or to be coupled to one of one or more selected nodes of the circuit design and comprising one or more threshold-comparing sub-convertors, each of the one or more threshold-comparing sub-convertors configured to output a bit value at one of outputs of the each of the one or more threshold-comparing convertors based on comparing a voltage value at the one of one or more selected nodes with one of one or more preset thresholds,
wherein in the scan-based structural testing of circuits, at least some bits of the plurality of sets of bit values are applied to each of the circuits using one or more scan chains in the each of the circuits and test response bit values at at least some of the outputs of the one or more threshold-comparing convertors are captured by the one or more scan chains.

15. The one or more non-transitory computer-readable media recited in claim 14, wherein the bit value outputted by the each of the one or more threshold-comparing sub-convertors is treated as being indeterminate if the voltage value at the one of one or more selected nodes is within a preset range centered at the one of the one or more preset thresholds.

16. The one or more non-transitory computer-readable media recited in claim 14, wherein the bit value outputted by the each of the one or more threshold-comparing sub-convertors is treated as being indeterminate if the performing a simulation is repeated for different combinations of process parameter values and the bit value is not the same for all of the different combinations of process parameter values.

17. The one or more non-transitory computer-readable media recited in claim 14, wherein the plurality of sets of bit values are generated based on random combinations of bit values or all combinations of bit values.

18. The one or more non-transitory computer-readable media recited in claim 14, wherein the one or more selected internal nodes and the one or more selected nodes are selected based on user specification, circuit topology, or both.

19. The one or more non-transitory computer-readable media recited in claim 14, wherein the number of bit values at inputs of the each of the one or more input node-connecting devices is either 1 or 2 and each of at least some of the one or more node-connecting devices is configured to cause, based on a 2-bit value, a selected internal node to be coupled to either or neither of two other nodes of the circuit.

20. The one or more non-transitory computer-readable media recited in claim 14, wherein the method further comprises:
injecting defects into the circuit design; and
performing the operations recited in claim 1 to determine a set of test patterns that can detect at least some of the defects.
